(19) United States
(12) Patent Application Publication
(10) Pub. No.: US 2026/0101562 A1
(43) Pub. Date: Apr. 9, 2026

(54) TRANSISTOR, INVERTER AND MANUFACTURING METHOD OF THE SAME, AND MEMORY UNIT

(71) Applicant: Industrial Technology Research Institute, Hsinchu (TW)

(72) Inventors: Haw-Tyng Huang, Taipei City (TW); Po-Chun Yeh, Taichung City (TW); Hsien-Yi Liao, Hsinchu County (TW); Yao-Cing Han, Hsinchu County (TW); Chi-Yuan Kuo, New Taipei City (TW); Chih-I Wu, Taipei City (TW); Hsiang-Chun Wang, Taichung City (TW)

(73) Assignee: Industrial Technology Research Institute, Hsinchu (TW)

(21) Appl. No.: 18/961,449

(22) Filed: Nov. 27, 2024

(30) Foreign Application Priority Data
Oct. 8, 2024 (TW) 113138234

(51) Int. Cl. H10D 64/27; H01L 23/498; H10B 10/00; H10D 64/01

(52) U.S. Cl. CPC H10D 64/513; H10B 10/12; H10D 64/027; H10D 64/518; H10D 64/519; H10W 70/658

(57) ABSTRACT

A transistor, an inverter, a manufacturing method of an inverter and a memory unit are provided. The transistor including a substrate, a stacked structure, and a gate structure. The stacked structure is disposed on the substrate and includes a drain electrode, a source electrode, a semiconductor layer, a first buffer layer, and a second buffer layer. The gate structure includes a gate electrode and a gate dielectric layer. By forming the doped region in the buffer layer to dispose the channel region contact between the source electrode and the drain electrode, the channel layer having the vertical structure is formed, and thereby the vertical transistor having a novel structure is formed. By stacking two transistors on the substrate and allowing the two transistors to share the gate structure, the inverter can have the three-dimensional structure, and the area of the inverter can be reduced to have a relatively small dimension.

### CROSS-REFERENCE TO RELATED APPLICATION

This application claims the priority benefit of Taiwan application serial no. 113138234, filed on Oct. 8, 2024. The entirety of the above-mentioned patent application is hereby incorporated by reference herein and made a part of this specification.

### BACKGROUND

### Technical Field

The disclosure relates to a transistor, an inverter, and a memory unit.

### Description of Related Art

In the back-end of line (BEOL) process of electronic devices, the density of mutually compatible logic operation units is low, occupying a relatively large space. Accordingly, if the occupied space of the logic operation units can be reduced, the area utilization efficiency of electronic devices can be improved.

### SUMMARY

Some embodiments of the disclosure provide a transistor, which includes a substrate, a stacked structure, and a gate structure. The stacked structure is disposed on the substrate and includes a drain electrode, a source electrode, a semiconductor layer, a first buffer layer, and a second buffer layer. The source electrode is disposed on the drain electrode. The semiconductor layer is disposed between the drain electrode and the source electrode. The first buffer layer is disposed between the drain electrode and the semiconductor layer. The second buffer layer is disposed between the source electrode and the semiconductor layer. The gate structure is disposed on the substrate, in which the gate structure extends in a top-down direction of the substrate and penetrates the stacked structure. The gate structure includes a gate electrode and a gate dielectric layer. The gate dielectric layer is disposed between the gate electrode and the stacked structure.

Some embodiments of the disclosure provide an inverter, which includes a substrate, a stacked structure, a gate structure, and a second semiconductor layer. The stacked structure is disposed on the substrate and includes a first stacked structure and a second stacked structure disposed on the first stacked structure. The first stacked structure includes a first source electrode, a first drain electrode, a first semiconductor layer, a first buffer layer, and a second buffer layer. The first drain electrode is disposed on the first source electrode. The first semiconductor layer is disposed between the first source electrode and the first drain electrode. The first buffer layer is disposed between the first source electrode and the first semiconductor layer. The second buffer layer is disposed between the first drain electrode and the first semiconductor layer. The second stacked structure includes a second drain electrode, a second source electrode, and an insulating layer. The second source electrode is disposed on the second drain electrode. The insulating layer is disposed between the second drain electrode and the second source electrode. The gate structure is disposed on the substrate, in which the gate structure extends in the top-down direction of the substrate and penetrates the stacked structure. The gate structure includes a gate electrode and a gate dielectric layer. The gate dielectric layer is disposed between the gate electrode and the stacked structure. The second semiconductor layer is disposed between the gate structure and the second stacked structure, in which the second semiconductor layer is in contact with the second source electrode and the second drain electrode.

Some embodiments of the disclosure provide a manufacturing method of an inverter, which includes the following steps. (A) A first stacked structure material layer including a first semiconductor layer is formed. (B) A second stacked structure material layer is formed on the first stacked structure material layer. (C) A first contact window and a second contact window are formed, in which the first contact window is electrically connected to the first source electrode and the first drain electrode in the first stacked structure material layer, and the second contact window is electrically connected to the second source electrode and the second drain electrode in the second stacked structure material layer. (D) A portion of the second stacked structure material layer is removed to form a first trench, and a second semiconductor layer is formed in the first trench, in which the second semiconductor layer is in contact with the second source electrode and the second drain electrode. (E) A portion of the first stacked structure material layer is removed through the first trench to form a second trench, in which a width of the second trench is smaller than a width of the first trench. (F) A gate structure filled in the first trench and the second trench is formed.

Some embodiments of the disclosure provide a memory unit, which includes a first inverter and a second inverter cross-coupled to each other. The first inverter and the second inverter are the inverters described in the above embodiments. The first inverter and the second inverter share the first source electrode and the first semiconductor layer.

### BRIEF DESCRIPTION OF THE DRAWINGS

FIG. 1 is a schematic flowchart of a manufacturing method of a transistor according to an embodiment of the disclosure.

FIG. 2A to FIG. 2F are flow diagrams of a manufacturing method of an inverter according to an embodiment of the disclosure.

FIG. 3 is a circuit diagram of the inverter according to an embodiment of the disclosure.

FIG. 4 is a partial cross-sectional schematic diagram of a memory unit according to an embodiment of the disclosure.

FIG. 5 is a circuit diagram of the memory unit according to an embodiment of the disclosure.

### DETAILED DESCRIPTION

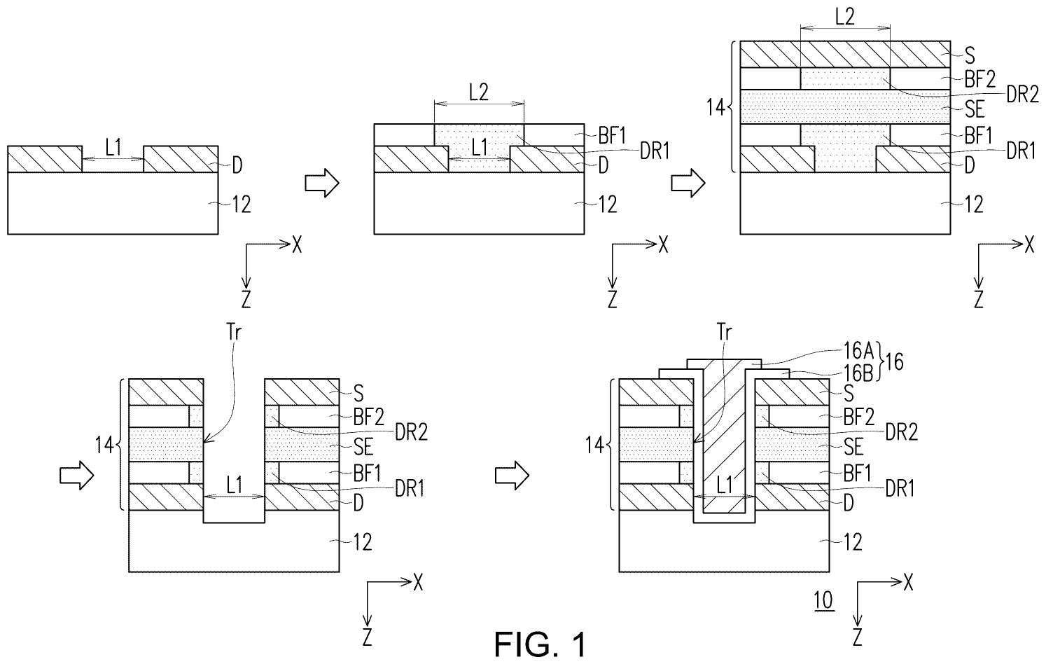

FIG. 1 is a schematic flowchart of a manufacturing method of a transistor 10 according to an embodiment of the disclosure.

Referring to FIG. 1, in this embodiment, the transistor 10 may be formed by performing the following steps, but the disclosure is not limited thereto.

Step (1) is performed: A drain electrode D is formed on a substrate 12.

The drain electrode D may be disposed on the substrate 12. In some embodiments, the substrate 12 may be a semiconductor substrate, but the disclosure is not limited thereto. In some embodiments, the material of the substrate 12 may include element semiconductors, compound semiconductors, alloy semiconductors, or other suitable materials. For example, the material of the substrate 12 may include silicon, germanium, indium antimonide, indium arsenide, indium phosphide, gallium nitride, gallium arsenide, gallium antimonide, lead telluride, or combinations thereof. In other embodiments, the substrate 12 may also be a silicon on insulator (SOI) substrate.

In some embodiments, the drain electrode D may be formed by performing the following steps, but the disclosure is not limited thereto. First, by performing a chemical vapor deposition (CVD) process, a physical vapor deposition (PVD) process, or an atomic layer deposition (ALD) process, a drain electrode material layer is formed. Afterward, a patterning process is performed on the drain electrode material layer to form the drain electrode D. In this embodiment, the drain electrode D has a ring-shaped structure in a top-down direction Z of the substrate 12. This means that the drain electrode D has an opening exposing a portion of the substrate 12 in a direction perpendicular to the top-down direction Z (for example, a direction X), which the opening has a dimension L1 in the direction perpendicular to the top-down direction Z (for example, the direction X) of the substrate 12. In some embodiments, the ring-shaped structure of the drain electrode D is a circular annular structure, and the opening thereof is a circular opening, but the disclosure is not limited thereto. In some embodiments, the material of the drain electrode D may include a suitable metal or metal alloy. For example, the material of the drain electrode D may include copper (Cu), aluminum (Al), tungsten (W), nickel (Ni), cobalt (Co), or combinations thereof, but the disclosure is not limited thereto.

Step (2) is performed: A buffer layer BF1 is formed on the substrate 12.

The buffer layer BF1 may be disposed on the substrate 12. In some embodiments, the buffer layer BF1 may cover the drain electrode D disposed on the substrate 12 and may fill the opening of the drain electrode D. In some embodiments, the buffer layer BF1 may be formed by performing the atomic layer deposition process, but the disclosure is not limited thereto. In some embodiments, the material of the buffer layer BF1 may include an oxide semiconductor. For example, the material of the buffer layer BF1 may include copper oxide (CuO), nickel oxide (NiO), bismuth oxide (Bi₂O₃), or other suitable oxide semiconductors, but the disclosure is not limited thereto.

Step (3) is performed: A doped region DR1 is formed in the buffer layer BF1.

In some embodiments, the doped region DR1 may overlap the opening of the drain electrode D in the top-down direction Z of the substrate 12 and have a dimension L2 in the direction X. In this embodiment, the dimension L2 of the doped region DR1 is larger than the dimension L1 of the opening of the drain electrode D. Therefore, a portion of the doped region DR1 overlaps the drain electrode D in the top-down direction Z of the substrate 12. In some embodiments, the doped region DR1 may be formed by performing an ion implantation process, but the disclosure is not limited thereto. In some embodiments, the doped region DR1 may include heavily doped n-type impurities. For example, the doped region DR1 may include phosphorus or arsenic, but the disclosure is not limited thereto.

Step (4) is performed: A semiconductor layer SE is formed on the buffer layer BF1.

The semiconductor layer SE may be disposed on the buffer layer BF1. In some embodiments, the semiconductor layer SE may cover the buffer layer BF1. In this embodiment, the semiconductor layer SE is formed by using low temperature polysilicon (LTPS) technology. Based on above, in this embodiment, the material of the semiconductor layer SE may include polysilicon. More specifically, the semiconductor layer SE may cover the buffer layer BF1, and the semiconductor layer SE may cover the doped region DR1.

Step (5) is performed: A buffer layer BF2 is formed on the semiconductor layer SE.

The buffer layer BF2 may be disposed on the semiconductor layer SE. In some embodiments, the buffer layer BF2 may the cover semiconductor layer SE. In some embodiments, the buffer layer BF2 may be formed by performing the same or similar process as the buffer layer BF1, but the disclosure is not limited thereto. In some embodiments, the material of the buffer layer BF2 may include an oxide semiconductor. For example, the material of the buffer layer BF2 may include copper oxide (CuO), nickel oxide (NiO), bismuth oxide (Bi₂O₃), or other suitable oxide semiconductors, but the disclosure is not limited thereto.

Step (6) is performed: A doped region DR2 is formed in the buffer layer BF2.

In some embodiments, the doped region DR2 has a width L2 on the direction X. In some embodiments, the doped region DR2 may be formed by performing the same or similar process as the doped region DR1, but the disclosure is not limited thereto. In some embodiments, the doped region DR2 may include heavily doped n-type impurities. For example, the doped region DR2 may include phosphorus or arsenic, but the disclosure is not limited thereto.

Step (7) is performed: A source electrode S is formed on the buffer layer BF2.

The source electrode S may be disposed on the buffer layer BF2. In some embodiments, the source electrode S may be formed by performing the chemical vapor deposition process, the physical vapor deposition process, or the atomic layer deposition process, but the disclosure is not limited thereto. In some embodiments, the material of the source electrode S may include a suitable metal or metal alloy. For example, the material of the source electrode S may include copper, aluminum, tungsten, nickel, cobalt, or combinations thereof, but the disclosure is not limited thereto.

Step (8) is performed: a trench Tr penetrating the source electrode S, the buffer layer BF2, the semiconductor layer SE, and the buffer layer BF1 is formed.

In some embodiments, the trench Tr may be formed by performing a suitable patterning process. A sidewall of the trench Tr exposes the source electrode S, the buffer layer BF2, the semiconductor layer SE, and the buffer layer BF1, and a bottom of the trench Tr exposes the substrate 12. More specifically, a portion of the source electrode S, the buffer layer BF2, the semiconductor layer SE, and the buffer layer BF1 may be removed to form the trench Tr, in which the substrate 12 may be used as an etching stop layer, but the disclosure is not limited thereto. In this embodiment, the trench Tr overlaps the opening of the drain electrode D in the direction perpendicular to the top-down direction Z (for example, the direction X), and the trench Tr has the dimension L1 in the direction X. In this embodiment, the trench Tr has a circular structure (or cylindrical structure) in the top-down direction Z of the substrate 12, but the disclosure is not limited thereto.

In this embodiment, the formation of the trench Tr removes most of the doped region DR1 and the doped region DR2. Since the dimension L2 of the doped region DR1 and the doped region DR2 in the direction X is greater than the dimension L1 of the trench Tr in the direction X, there is still a portion of the doped region DR1 disposed in the buffer layer BF1 and a portion of the doped region DR2 disposed in the buffer layer BF2 left, which are exposed by the sidewall of the trench Tr.

Step (9) is performed: A gate dielectric layer 16B is formed in the trench Tr.

In some embodiments, the gate dielectric layer 16B may be formed by performing the following steps, but the disclosure is not limited thereto. First, by performing the chemical vapor deposition process, the physical vapor deposition process, or the atomic layer deposition process, a gate insulating material layer is formed. Afterward, a patterning process is performed on the gate insulating material layer to form the gate dielectric layer 16B. In this embodiment, the gate dielectric layer 16B is conformally formed on the sidewall of the trench Tr, and covers the source electrode S, the doped region DR2, the semiconductor layer SE, the doped region DR1, and the drain electrode D exposed by the sidewall of the trench Tr. In some embodiments, the gate dielectric layer 16B may also conformally cover a portion of the exposed substrate 12. In some embodiments, the material of the gate dielectric layer 16B may include suitable dielectric materials. For example, the material of the gate dielectric layer 16B may include silicon oxide (SiO₂), silicon nitride (Si₃N₄), aluminum oxide (Al₂O₃), tantalum oxide (Ta₂O₅), titanium oxide (TiO₂), zinc oxide (ZnO₂), or hafnium oxide (HfO₂), but the disclosure is not limited thereto.

Step (10) is performed: A gate electrode 16A is formed in the trench Tr.

In some embodiments, the gate electrode 16A may be formed by performing the following steps, but the disclosure is not limited thereto. First, by performing the chemical vapor deposition process, the physical vapor deposition process, or the atomic layer deposition process, a gate material layer is formed. Afterward, a patterning process is performed on the gate material layer to form the gate electrode 16A. In this embodiment, the gate electrode 16A is filled in the trench Tr, and the gate electrode 16A and the gate dielectric layer 16B may form a gate structure 16. In some embodiments, the material of the gate electrode 16A may include a suitable metal or metal alloy. For example, the material of the gate electrode 16A may include copper, aluminum, tungsten, nickel, cobalt, or combinations thereof, but the disclosure is not limited thereto.

At this point, the manufacturing method of the transistor 10 of this embodiment is completed, but the manufacturing method of the transistor 10 provided by the disclosure is not limited thereto.

The structure of the transistor 10 of this embodiment will be briefly introduced below with reference to FIG. 1, but the disclosure is not limited thereto.

In this embodiment, the transistor 10 is a vertical transistor formed using low temperature polysilicon technology, and includes the substrate 12, a stacked structure 14, and the gate structure 16.

For the rest of the introduction related to the substrate 12, reference may be made to the above embodiments, so details will not be repeated here.

More specifically, the stacked structure 14 may be disposed on the substrate 12. In this embodiment, the stacked structure 14 includes a stack formed by the drain electrode D, the source electrode S, the semiconductor layer SE, the buffer layer BF1, and the buffer layer BF2, in which the drain electrode D, the buffer layer BF1, the semiconductor layer SE, the buffer layer BF2, and the source electrode S are stacked on the substrate 12 in such a sequence from bottom to top, but the disclosure is not limited thereto.

More specifically, the drain electrode D may be disposed on the substrate 12. In some embodiments, the drain electrode D may have a ring-shaped structure in the top-down direction Z of the substrate 12. For the rest of the introduction related to the drain electrode D, reference may be made to the above embodiments, so details will not be repeated here.

More specifically, the source electrode S may be disposed on the drain electrode D. In some embodiments, the source electrode S has a ring-shaped structure in the top-down direction Z of the substrate 12. The source electrode S may, for example, have a similar shape to the drain electrode D in the top-down direction Z of the substrate 12, but the disclosure is not limited thereto. For the rest of the introduction related to the source electrode S, reference may be made to the above embodiments, so details will not be repeated here.

More specifically, the semiconductor layer SE may be disposed between the drain electrode D and the source electrode S. As mentioned above, the transistor 10 is formed using low temperature polysilicon technology. Therefore, in this embodiment, the material of the semiconductor layer SE may include polysilicon. For the rest of the introduction related to the semiconductor layer SE, reference may be made to the above embodiments, so details will not be repeated here.

More specifically, the buffer layer BF1 may be disposed between the drain electrode D and the semiconductor layer SE. In this embodiment, the material of the buffer layer BF1 may include an oxide semiconductor. In some embodiments, the oxide semiconductor included in the buffer layer BF1 may have a band gap of 2.0 eV to 3.0 eV, but the disclosure is not limited thereto. In this embodiment, the buffer layer BF1 may include the doped region DR1, in which the doped region DR1 may be in direct contact with the semiconductor layer SE, the doped region DR1 may be in direct contact with the drain electrode D, and the doped region DR1 includes heavily doped n-type impurities. Accordingly, the buffer layer BF1 may include an area with relatively high conductivity (the doped region DR1) and an area with relatively low conductivity (area outside the doped region DR1). For the rest of the introduction related to the buffer layer BF1 and the doped region DR1, reference may be made to the above embodiments, so details will not be repeated here.

More specifically, the buffer layer BF2 may be disposed between the source electrode S and the semiconductor layer SE. In this embodiment, the material of the buffer layer BF2 may include an oxide semiconductor. In some embodiments, the oxide semiconductor included in the buffer layer BF2 may have a band gap of 2.0 eV to 3.0 eV, but the disclosure is not limited thereto. In this embodiment, the buffer layer BF2 may include the doped region DR2, in which the doped region DR2 may be in direct contact with the semiconductor layer SE, the doped region DR2 may be in direct contact with the source electrode S, and the doped region DR2 includes heavily doped n-type impurities. Accordingly, the buffer layer BF2 may include an area with relatively high conductivity (the doped region DR2) and an area with relatively low conductivity (area outside the doped region DR2). For the rest of the introduction related to the buffer layer BF2 and the doped region DR2, reference may be made to the above embodiments, so details will not be repeated here.

In some embodiments, the doped region DR1 in the buffer layer BF1 and the doped region DR2 in the buffer layer BF2 may serve as a contact fora channel region. More specifically, in this embodiment, the doped region DR1, the doped region DR2, and the semiconductor layer SE positioned between the doped region DR1 and the doped region DR2 in the top-down direction Z of the substrate 12 may form a channel layer of the transistor 10. Accordingly, the channel layer has a vertical structure extending along the top-down direction Z of the substrate 12, so that the transistor 10 of this embodiment is a vertical transistor.

In some embodiments, the gate structure 16 may be disposed on the substrate 12. In this embodiment, the gate structure 16 extends in the top-down direction Z of the substrate 12 and penetrates the stacked structure 14. More specifically, the stacked structure 14 may have a through hole penetrated by the gate structure 16, the through hole is formed by the sidewall of the trench Tr, and the gate structure 16 has a columnar structure in the top-down direction Z of the substrate 12. In some embodiments, the gate structure 16 has a cylindrical structure in the top-down direction Z of the substrate 12, but the disclosure is not limited thereto. In this embodiment, the gate structure 16 may include the gate electrode 16A and the gate dielectric layer 16B.

More specifically, the gate electrode 16A may be filled in the trench Tr. In this embodiment, the gate electrode 16A partially overlaps the semiconductor layer SE in the direction X. For the rest of the introduction related to the gate electrode 16A, reference may be made to the above embodiments, so details will not be repeated here.

More specifically, the gate dielectric layer 16B may be disposed between the gate electrode 16A and stacked structure 14. In this embodiment, the gate dielectric layer 16B may be conformally disposed on the sidewall of the trench Tr and on the surface of the substrate 12 exposed by the trench Tr. Accordingly, the gate dielectric layer 16B may be in contact with the doped region DR1 in the buffer layer BF1 and the doped region DR2 in the buffer layer BF2. For the rest of the description of the gate dielectric layer 16B, reference may be made to the foregoing embodiments and will not be described again here.

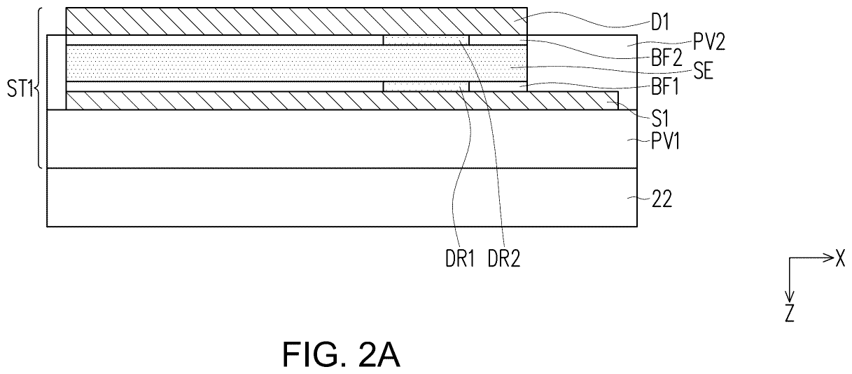

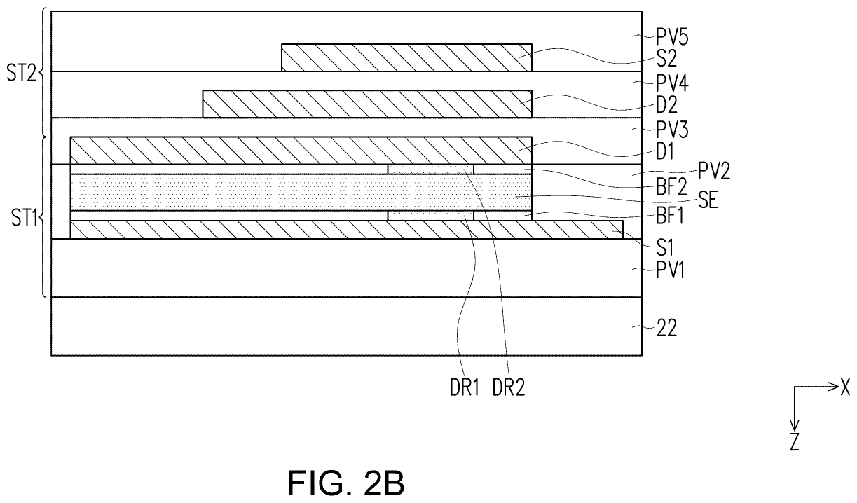

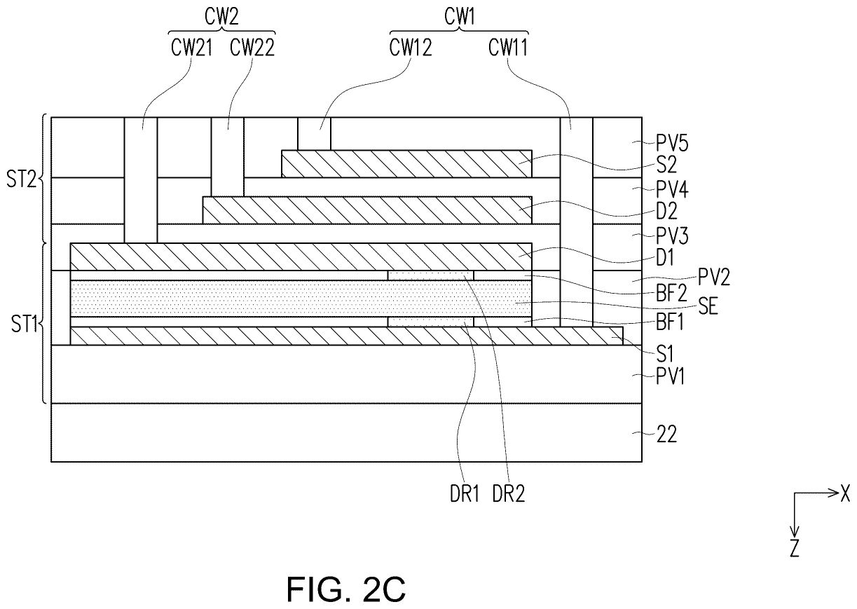

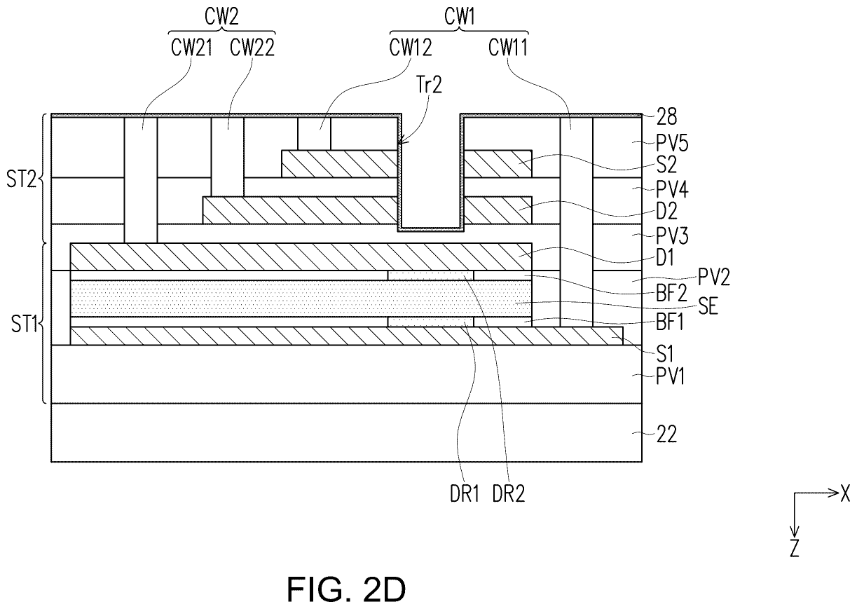

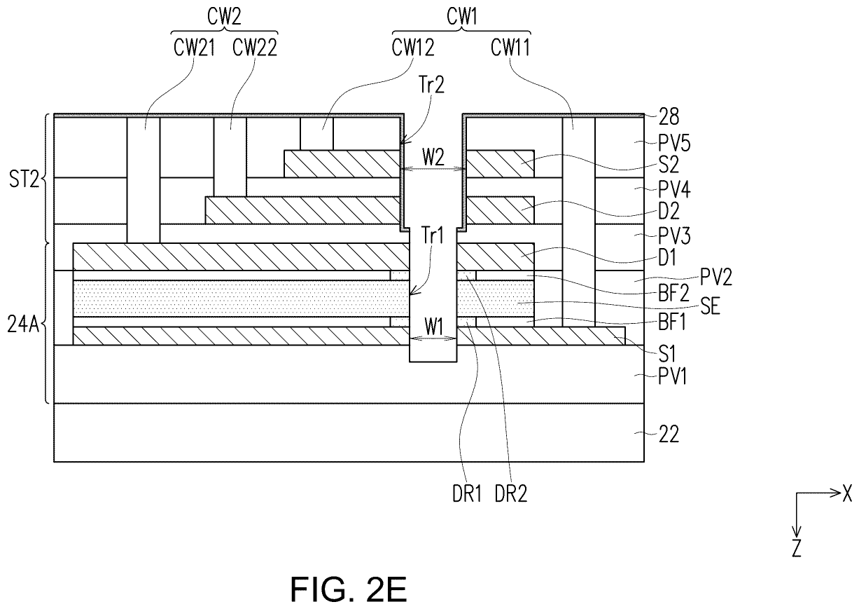

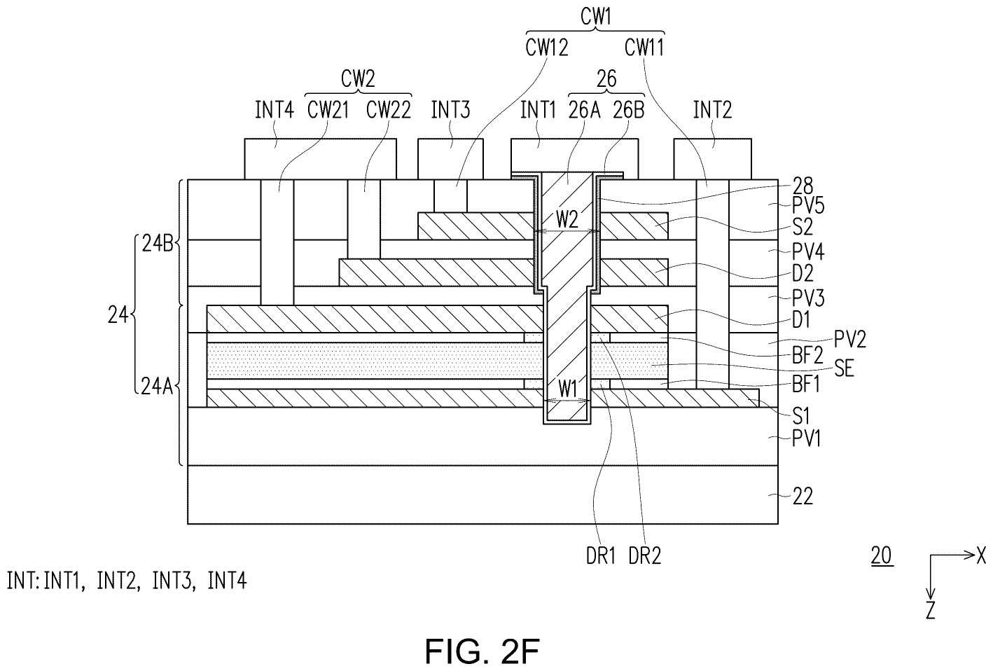

FIG. 2A to FIG. 2F are flow diagrams of a manufacturing method of an inverter according to an embodiment of the disclosure.

In this embodiment, an inverter 20 may be formed by performing the following steps, but the disclosure is not limited thereto.

Step (A) is performed: A first stacked structure material layer ST1 is formed on a substrate 22.

Referring to FIG. 2A, in this embodiment, the first stacked structure material layer ST1 may include an insulating layer PV1, a source electrode S1, the buffer layer BF1, the semiconductor layer SE, the buffer layer BF2, a drain electrode D1, and an insulating layer PV2, but the disclosure is not limited thereto.

More specifically, the insulating layer PV1 may be disposed on the substrate 22. In some embodiments, the insulating layer PV1 may be formed by performing a thermal oxidation process, but the disclosure is not limited thereto. In some embodiments, the material of the insulating layer PV1 may include oxide. For example, the material of the insulating layer PV1 may include silicon oxide, but the disclosure is not limited thereto.

More specifically, the source electrode S1 may be disposed on the insulating layer PV1. In some embodiments, the source electrode S1 may be formed by performing the chemical vapor deposition process, the physical vapor deposition process, or the atomic layer deposition process, but the disclosure is not limited thereto. In some embodiments, the material of the source electrode S1 may include a suitable metal or metal alloy. For example, the material of the source electrode S1 may include copper, aluminum, tungsten, nickel, cobalt, or combinations thereof, but the disclosure is not limited thereto.

More specifically, the buffer layer BF1 may be disposed on the insulating layer PV1, and may be disposed on a portion of the source electrode S1. In some embodiments, the buffer layer BF1 may be formed by performing the atomic layer deposition process, but the disclosure is not limited thereto. In some embodiments, the material of the buffer layer BF1 may include an oxide semiconductor. For example, the material of the buffer layer BF1 may include copper oxide, nickel oxide, bismuth oxide, or other suitable oxide semiconductors, but the disclosure is not limited thereto. It is worth noting that the doped region DR1 may also be formed in the buffer layer BF1 using the ion implantation process. For the introduction related to the doped region DR1, reference may be made to the above embodiments, so details will not be repeated here.

More specifically, the semiconductor layer SE may be disposed on the buffer layer BF1. In this embodiment, the semiconductor layer SE may be formed using low temperature polysilicon technology. Accordingly, in this embodiment, the material of the semiconductor layer SE may include polysilicon.

More specifically, the buffer layer BF2 may be disposed on the semiconductor layer SE. In some embodiments, the buffer layer BF2 may be formed by performing the same or similar process as buffer layer BF1, but the disclosure is not limited thereto. In some embodiments, the material of the buffer layer BF2 may include an oxide semiconductor. For example, the material of the buffer layer BF2 may include copper oxide, nickel oxide, bismuth oxide, or other suitable oxide semiconductors, and the disclosure is not limited thereto. It is worth noting that the doped region DR2 may also be formed in the buffer layer BF2 using the ion implantation process. For the introduction related to the doped region DR2, reference may be made to the above embodiments, so details will not be repeated here.

More specifically, the drain electrode D1 may be disposed on the buffer layer BF2. In some embodiments, the drain electrode D1 may be formed by performing the chemical vapor deposition process, the physical vapor deposition process, or the atomic layer deposition process, but the disclosure is not limited thereto. In some embodiments, the material of the drain electrode D1 may include a suitable metal or metal alloy. For example, the material of the drain electrode D1 may include copper, aluminum, tungsten, nickel, cobalt, or combinations thereof, but the disclosure is not limited thereto.

In some embodiments, the insulating layer PV2 may be disposed on the insulating layer PV1, and may be disposed on other portions of the source electrode S1 exposed by the buffer layer BF1. More specifically, the insulating layer PV2 may further cover the buffer layer BF2, the semiconductor layer SE, and the buffer layer BF1, and the drain electrode D1 may further be disposed on the insulating layer PV2. In some embodiments, the insulating layer PV2 may be formed by performing the chemical vapor deposition process, the physical vapor deposition process, or the atomic layer deposition process, but the disclosure is not limited thereto. In some embodiments, the material of the insulating layer PV2 may include suitable dielectric materials. For example, the material of the insulating layer PV2 may include silicon oxide, silicon nitride, silicon oxynitride, or combinations thereof, but the disclosure is not limited thereto.

Step (B) is performed: A second stacked structure material layer ST2 is formed on the first stacked structure material layer ST1.

Referring to FIG. 2B, in this embodiment, the second stacked structure material layer ST2 is disposed on the first stacked structure material layer ST1. The second stacked structure material layer ST2 may include an insulating layer PV3, a drain electrode D2, an insulating layer PV4, a source electrode S2, and an insulating layer PV5, but the disclosure is not limited thereto.

More specifically, the insulating layer PV3 may be disposed on the buffer layer BF2 and may cover the drain electrode D1. In this embodiment, the insulating layer PV3 may further cover the drain electrode D1. In some embodiments, the insulating layer PV3 may be formed by performing the chemical vapor deposition process, the physical vapor deposition process, or the atomic layer deposition process, but the disclosure is not limited thereto. In some embodiments, the material of the insulating layer PV3 may include suitable dielectric materials. For example, the material of the insulating layer PV3 may include silicon oxide, silicon nitride, silicon oxynitride, or combinations thereof, but the disclosure is not limited thereto.

More specifically, the drain electrode D2 may be disposed on the insulating layer PV3. In some embodiments, the drain electrode D2 may be formed by performing the same or similar process as the drain electrode D1, but the disclosure is not limited thereto. In some embodiments, the material of the drain electrode D2 may include a suitable metal or metal alloy. For example, the material of the drain electrode D2 may include copper, aluminum, tungsten, nickel, cobalt, or combinations thereof, but the disclosure is not limited thereto.

More specifically, the insulating layer PV4 may be disposed on the insulating layer PV3, and may cover the drain electrode D2. In this embodiment, the insulating layer PV4 may further cover the drain electrode D2. In some embodiments, the insulating layer PV4 may be formed by performing the chemical vapor deposition process, the physical vapor deposition process, or the atomic layer deposition process, but the disclosure is not limited thereto. In some embodiments, the material of the insulating layer PV4 may include suitable dielectric materials. For example, the material of the insulating layer PV4 may include silicon oxide, silicon nitride, silicon oxynitride, or combinations thereof, but the disclosure is not limited thereto.

More specifically, the source electrode S2 may be disposed on the insulating layer PV4. In some embodiments, the source electrode S2 may be formed by performing the same or similar process as the source electrode S1, but the disclosure is not limited thereto. In some embodiments, the material of the source electrode S2 may include a suitable metal or metal alloy. For example, the material of the source electrode S2 may include copper, aluminum, tungsten, nickel, cobalt, or combinations thereof, but the disclosure is not limited thereto.

More specifically, the insulating layer PV5 may be disposed on the insulating layer PV4, and may cover the source electrode S2. In this embodiment, the insulating layer PV5 may further cover the source electrode S2. In some embodiments, the insulating layer PV5 may be formed by performing the chemical vapor deposition process, the physical vapor deposition process, or the atomic layer deposition process, but the disclosure is not limited thereto. In some embodiments, the material of the insulating layer PV5 may include suitable dielectric materials. For example, the material of the insulating layer PV5 may include silicon oxide, silicon nitride, silicon oxynitride, or combinations thereof, but the disclosure is not limited thereto.

Step (C) is performed: A contact window CW1 and a contact window CW2 are formed.

Referring to FIG. 2C, in this embodiment, the contact window CW1 may be electrically connected to the source electrode S1 and the source electrode S2, and the contact window CW2 may be electrically connected to the drain electrode D1 and the drain electrode D2 in the second stacked structure material layer ST2. In some embodiments, the contact window CW1 and the contact window CW2 may include suitable conductive materials, but the disclosure is not limited thereto.

More specifically, the contact window CW1 may include a contact window CW11 and a contact window CW12. In some embodiments, the contact window CW11 may penetrate the insulating layer PV2, the insulating layer PV3, the insulating layer PV4, and the insulating layer PV5 to be electrically connected to the source electrode S1, and the contact window CW12 may penetrate the insulating layer PV5 to be electrically connected to the drain electrode D1.

More specifically, the contact window CW2 may include a contact window CW21 and a contact window CW22. In some embodiments, the contact window CW21 may penetrate the insulating layer PV3, the insulating layer PV4, and the insulating layer PV5 to be electrically connected to the drain electrode D1, and the contact window CW22 may penetrate the insulating layer PV4 and the insulating layer PV5 to be electrically connected to the drain electrode D2.

In some embodiments, the contact windows CW11, CW12, CW21, and CW22 may be formed sequentially through a suitable deposition process after first performing a patterning process on the corresponding insulating layer, but the disclosure is not limited thereto.

Step (D) is performed: A portion of the second stacked structure material layer ST2 is removed to form a trench Tr2, and a semiconductor layer 28 is formed in the trench Tr2.

Referring to FIG. 2D, in some embodiments, the trench Tr2 may be formed by performing a suitable patterning process, in which a sidewall of the trench Tr2 exposes the insulating layer PV5, the source electrode S2, the insulating layer PV4, and the drain electrode D2, and a bottom of the trench Tr2 exposes the insulating layer PV3. More specifically, a portion of the insulating layer PV5, the source electrode S2, the insulating layer PV4, and the drain electrode D2 may be removed from a surface of the second stacked structure material layer ST2 to form the trench Tr2, in which the insulating layer PV3 may be used as an etching stop layer, but the disclosure is not limited thereto.

In some embodiments, the semiconductor layer 28 may be formed by performing the atomic layer deposition process. In this embodiment, the material of the semiconductor layer 28 includes an oxide semiconductor. For example, the material of the semiconductor layer 28 may include indium gallium oxide (IGO), indium tungsten oxide (IWO), indium gallium zinc oxide (IGZO), or other suitable oxide semiconductors, and the disclosure is not limited thereto. In some embodiments, the semiconductor layer 28 may be conformally formed in the trench Tr2 and on the surface of the second stacked structure material layer ST2. More specifically, the semiconductor layer 28 may be conformally formed in the trench Tr2, and cover the contact window CW1, the contact window CW2, and the insulating layer PV5, but the disclosure is not limited thereto.

Step (E) is performed: A portion of the first stacked structure material layer ST1 is removed through the trench Tr2 to form a trench Tr1.

Referring to FIG. 2E, in some embodiments, the trench Tr1 may be formed by performing a suitable patterning process. In this embodiment, the trench Tr1 overlaps the trench Tr2 in the top-down direction Z of the substrate 22. More specifically, in this embodiment, the patterning process is performed from the bottom of the trench Tr2. In this embodiment, a width W1 of the trench Tr1 in the direction X is smaller than a width W2 of the trench Tr2 in the direction X. In some embodiments, the width W1 and the width W2 are less than or equal to 5 microns, but the disclosure is not limited thereto.

In some embodiments, a sidewall of the trench Tr1 exposes the insulating layer PV3, the drain electrode D1, the buffer layer BF2 (the doped region DR2), the semiconductor layer SE, the buffer layer BF1 (the doped region DR1), and the source electrode S1, and a bottom of the trench Tr1 exposes the insulating layer PV1. More specifically, a portion of the insulating layer PV3, the drain electrode D1, the buffer layer BF2, the semiconductor layer SE, the buffer layer BF1, and the source electrode S1 may be removed from the bottom of the trench Tr2 to form the trench Tr1, in which the insulating layer PV1 may be used as an etching stop layer, but the disclosure is not limited thereto.

In this embodiment, after removing a portion of the first stacked structure material layer ST1, a stacked structure 24A is formed.

Step (F) is performed: a gate structure 26 filled in the trench Tr2 and the trench Tr1 is formed.

Referring to FIG. 2F, in this embodiment, the gate structure 26 may include a gate electrode 26A and a gate dielectric layer 26B, and may be formed by performing the following steps, but the disclosure is not limited thereto.

First, by performing the chemical vapor deposition process, the physical vapor deposition process, or the atomic layer deposition process, the gate dielectric layer 26B may be formed in the trench Tr1 and the trench Tr2. In this embodiment, the gate dielectric layer 26B may be conformally formed on a sidewall of the trench Tr1 and a sidewall of the trench Tr2, and cover the semiconductor layer 28 located in the trench Tr2 and the insulating layer PV3, the drain electrode D1, the buffer layer BF2 (the doped region DR2), the semiconductor layer SE1, the buffer layer BF1 (the doped region DR1), and the source electrode S1 exposed by the trench Tr1. In some embodiments, the material of the gate dielectric layer 26B may include suitable dielectric materials. For example, the material of the gate dielectric layer 26B may include silicon oxide, silicon nitride, aluminum oxide, tantalum oxide, titanium oxide, zinc oxide, or hafnium oxide, but the disclosure is not limited thereto.

In this embodiment, after the gate dielectric layer 26B is formed, the gate electrode 26A may be formed in the trench Tr1 and the trench Tr2 by performing the chemical vapor deposition process, the physical vapor deposition process, or the atomic layer deposition process. In this embodiment, the gate electrode 26A is filled in the trench Tr1 and the trench Tr2, and covers the semiconductor layer 28 on the surface of the second stacked structure material layer ST2 in the direction X. In some embodiments, the material of the gate electrode 26A may include a suitable metal or metal alloy. For example, the material of the gate electrode 26A may include copper, aluminum, tungsten, nickel, cobalt, or combinations thereof, but the disclosure is not limited thereto.

In this embodiment, after forming the gate dielectric layer 26B and the gate electrode 26A, a patterning process may be performed to expose the contact window CW1 and the contact window CW2, in which a portion of the semiconductor layer 28 is removed to form a stacked structure 24B.

It is worth noting that after the gate structure 26 is formed, an interconnection layer INT may be formed on the insulating layer PV5. In this embodiment, the interconnection layer INT may include an interconnection layer INT1, an interconnection layer INT2, an interconnection layer INT3, and an interconnection layer INT4, in which the interconnection layer INT1 is electrically connected to the gate electrode 26A, the interconnection layer INT2 is electrically connected to the contact window CW11, the interconnection layer INT3 is electrically connected to the contact window CW12, and the interconnection layer INT4 is electrically connected to the contact window CW2, but the disclosure is not limited thereto.

At this point, the manufacturing method of the inverter 20 of this embodiment is completed, but the manufacturing method of the inverter 20 provided by the disclosure is not limited thereto.

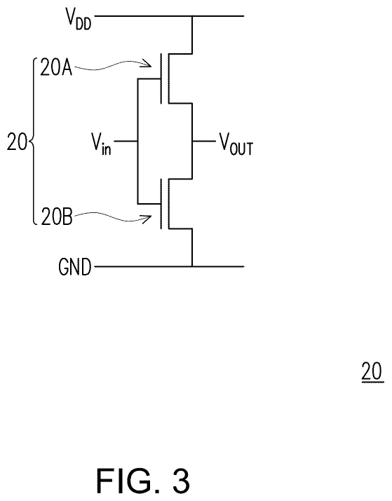

The structure of the inverter 20 of this embodiment will be briefly introduced below with reference to FIG. 2F and FIG. 3, in which FIG. 3 is a circuit diagram of the inverter according to an embodiment of the disclosure.

In this embodiment, the inverter 20 may be a complementary metal-oxide-semiconductor (CMOS) inverter. More specifically, the inverter 20 may be formed by a P-type transistor and an N-type transistor connected in series, in which the P-type transistor is a load transistor, and the N-type transistor is an input transistor, but the disclosure is not limited thereto.

Referring to FIG. 3 and FIG. 2F, in this embodiment, the inverter 20 includes a transistor 20A and a transistor 20B, in which the transistor 20A is a P-type transistor and the transistor 20B is a N-type transistor. In some embodiments, the transistor 20A may be disposed on the substrate 22, and may be disposed between the substrate 22 and the transistor 20B in the top-down direction Z of the substrate 22. In other words, the inverter 20 may be a structure including a P-type transistor and a N-type transistor stacked on top of each other. In addition, in this embodiment, the transistor 20A may be the transistor 10 of the above-mentioned embodiment. This means that the transistor 20A is also formed using low temperature polysilicon technology. In other embodiments, the transistor 20B may include an oxide semiconductor. Accordingly, the inverter 20 of this embodiment may be an inverter integrating a low temperature polysilicon film transistor and an oxide film transistor.

In this embodiment, the inverter 20 may further include an input line Vᵢₙ, a power line V_{DD}, a ground line GND, and an output line V_{OUT}. In some embodiments, the input line Vᵢₙ may be electrically connected to the gate electrode (the gate electrode 26A) of the transistor 20A and the transistor 20B, the power line V_{DD} may be electrically connected to the source electrode (the source electrode S1) of the transistor 20A, the ground line GND may be electrically connected to the source electrode (the source electrode S2) of the transistor 20B, and the output line V_{OUT} may be electrically connected to the drain electrodes (the drain electrode D1 and the drain electrode D2) of the transistor 20A and transistor 20B.

Referring to FIG. 2F, viewed from another perspective, the inverter 20 may include the substrate 22, the stacked structure 24, the gate structure 26, and the semiconductor layer 28.

For the rest of the introduction related to the substrate 22, reference may be made to the above embodiments, so details will not be repeated here.

More specifically, the stacked structure 24 may be disposed on the substrate 22 and may include a stacked structure 24A and a stacked structure 24B. In this embodiment, the stacked structure 24A is disposed between the substrate 22 and the stacked structure 24B in the top-down direction Z of the substrate 22.

More specifically, the stacked structure 24A may include a stack formed by the source electrode S1, the drain electrode D1, the semiconductor layer SE, the insulating layer PV1, the buffer layer BF1, and the buffer layer BF2, in which the insulating layer PV1, the source electrode S1, the buffer layer BF1, the semiconductor layer SE, the buffer layer BF2, and the drain electrode D1 are stacked on the substrate 22 in such a sequence from bottom to top, but the disclosure is not limited thereto. In some embodiments, the stacked structure 24A may further include the insulating layer PV2.

More specifically, the source electrode S1 may be disposed on the insulating layer PV1. In some embodiments, the source electrode S1 may have a ring-shaped structure in the top-down direction Z of the substrate 22. For the rest of the introduction related to the source electrode S1 and the insulating layer PV1, reference may be made to the above embodiments, so details will not be repeated here.

More specifically, the drain electrode D1 may be disposed on the source electrode S1. In some embodiments, the drain electrode D1 may have a ring-shaped structure in the top-down direction Z of the substrate 22. For the rest of the introduction related to the drain electrode D1, reference may be made to the above embodiments, so details will not be repeated here.

More specifically, the semiconductor layer SE may be disposed between the source electrode S1 and the drain electrode D1. In this embodiment, the semiconductor layer SE is formed using low temperature polysilicon technology. This means that the material of the semiconductor layer SE may include polysilicon. For the rest of the introduction related to the semiconductor layer SE, reference may be made to the above embodiments, so details will not be repeated here.

More specifically, the buffer layer BF1 may be disposed between the source electrode S1 and the semiconductor layer SE, and may be in contact with the semiconductor layer SE and the gate structure 26. In this embodiment, the buffer layer BF1 may include the doped region DR1. The doped region DR1 may include heavily doped n-type impurities. For example, the doped region DR1 may include phosphorus or arsenic, but the disclosure is not limited thereto. For the rest of the introduction related to the buffer layer BF1, reference may be made to the above embodiments, so details will not be repeated here.

More specifically, the buffer layer BF2 may be disposed between the drain electrode D1 and the semiconductor layer SE, and may be in contact with the semiconductor layer SE and the gate structure 26. In this embodiment, the buffer layer BF2 may include the doped region DR2. The doped region DR2 may include heavily doped n-type impurities. For example, the doped region DR2 may include phosphorus or arsenic, but the disclosure is not limited thereto. For the rest of the introduction related to the buffer layer BF2, reference may be made to the above embodiments, so details will not be repeated here.

More specifically, the stacked structure 24B may be disposed on the stacked structure 24A, and may include a stack formed by the source electrode S2, the drain electrode D2, the insulating layer PV3, the insulating layer PV4, and the insulating layer PV5, in which the insulating layer PV3, the drain electrode D2, the insulating layer PV4, the source electrode S2, and the insulating layer PV5 are stacked on the stacked structure 24A in such a sequence from bottom to top, but the disclosure is not limited thereto.

More specifically, the drain electrode D2 may be disposed on the insulating layer PV3. In some embodiments, the drain electrode D2 may have a ring-shaped structure in the top-down direction Z of the substrate 22. For the rest of the introduction related to the drain electrode D2 and the insulating layer PV3, reference may be made to the above embodiments, so details will not be repeated here.

More specifically, the source electrode S2 may be disposed on the drain electrode D2. In some embodiments, the source electrode S2 may have a ring-shaped structure in the top-down direction Z of the substrate 22. For the rest of the introduction related to the source electrode S2, reference may be made to the above embodiments, so details will not be repeated here.

More specifically, the insulating layer PV4 may be disposed between the drain electrode D2 and the electrode source S2. For the rest of the introduction related to the insulating layer PV4, reference may be made to the above embodiments, so details will not be repeated here.

More specifically, the insulating layer PV5 may be disposed on the source electrode S2. For the rest of the introduction related to the insulating layer PV5, reference may be made to the above embodiments, so details will not be repeated here.

In some embodiments, the gate structure 26 may be disposed on the substrate 22. In this embodiment, the gate structure 26 extends in the top-down direction Z of the substrate 22 and penetrates the stacked structure 24. More specifically, the stacked structure 24 may have a through hole penetrated by the gate structure 26, and the through hole is formed by the sidewalls of the trench Tr1 and the trench Tr2. In this embodiment, the width W1 of the trench Tr1 in the direction X is smaller than the width W2 of the trench Tr2 in the direction X. Accordingly, the sidewall of the through hole of the stacked structure 24 may have steps, so that the gate structure 26 has two columnar structures with different dimensions in the top-down direction Z of the substrate 22, but the disclosure is not limited thereto.

In this embodiment, the gate structure 26 may include the gate electrode 26A and the gate dielectric layer 26B.

More specifically, the gate electrode 26A may be filled in the trench Tr1 and the trench Tr2. In this embodiment, the gate electrode 26A overlaps a channel layer of the semiconductor layer SE in the direction X. For the rest of the introduction related to the gate electrode 26A, reference may be made to the above embodiments, so details will not be repeated here.

More specifically, the gate dielectric layer 26B may be disposed between the gate electrode 26A and the stacked structure 24. In this embodiment, the gate dielectric layer 26B may be conformally disposed on the sidewalls of the trench Tr1 and the trench Tr2 and on the surface of the substrate 22 exposed by the trench Tr1. Accordingly, the gate dielectric layer 26B may be in contact with the doped region DR1 in the buffer layer BF1 and the doped region DR2 in the buffer layer BF2. For the rest of the introduction related to the gate dielectric layer 26B, reference may be made to the above embodiments, so details will not be repeated here.

In some embodiments, the semiconductor layer 28 may be disposed between the gate structure 26 and the stacked structure 24B. In this embodiment, the semiconductor layer 28 is in contact with the source electrode S2 and the drain electrode D2. More specifically, the semiconductor layer 28 is in contact with the source electrode S2 and the drain electrode D2 exposed by the sidewall of the trench Tr2. In some embodiments, the material of the semiconductor layer 28 may include an oxide semiconductor. For example, the material of the semiconductor layer 28 may include indium gallium oxide, indium tungsten oxide, indium gallium zinc oxide, or other suitable oxide semiconductors, and the disclosure is not limited thereto.

In this embodiment, since the width W1 of the trench Tr1 in the direction X is smaller than the width W2 of the trench Tr2 in the direction X, the gate electrode 26A may have different widths in the direction X. More specifically, in this embodiment, the width of the gate electrode 26A surrounded by the semiconductor layer SE in the direction X is smaller than the width of the gate electrode 26A surrounded by the semiconductor layer 28 in the direction X.

In some embodiments, the width W1 of the gate structure 26 surrounded by the semiconductor layer SE in the direction X and the width W2 of the gate structure 26 surrounded by the semiconductor layer 28 in the direction X are less than or equal to 5 microns, but the disclosure is not limited thereto.

In summary, the transistor 20A may include the gate structure 26, the source electrode S1, the drain electrode D1, and the semiconductor layer SE located in the trench Tr1, and the transistor 20B may include the gate structure 26, the source electrode S2, the drain electrode D2, and the semiconductor layer 28 located in the trench Tr2. This means that, in this embodiment, the transistor 20A and the transistor 20B may share the gate structure 26.

In this embodiment, the doped region DR1 in the buffer layer BF1, the doped region DR2 in the buffer layer BF2, and the semiconductor layer SE positioned between the buffer layer BF1 and the buffer layer BF2 in the top-down direction Z of the substrate 22 may form a channel layer of the transistor 20A. Accordingly, the channel layer of the transistor 20A has a vertical structure extending along the top-down direction Z of the substrate 22, so that the transistor 20A of this embodiment is a vertical transistor. In addition, in this embodiment, the semiconductor layer 28 also has a vertical structure extending along the top-down direction Z of the substrate 22, so that the transistor 20B of this embodiment is also a vertical transistor.

In this embodiment, the inverter 20 may further include the interconnection layer INT. The interconnection layer INT may include the interconnection layer INT1, the interconnection layer INT2, the interconnection layer INT3, and the interconnection layer INT4. More specifically, the gate electrode 26A of the inverter 20 may be electrically connected to the interconnection layer INT1, and the gate electrode 26A may serve as an input terminal. The source electrode S1 of the inverter 20 may be electrically connected to the interconnection layer INT2 through the contact window CW11, and the source electrode S1 may serve as a power terminal. The source electrode S2 of the inverter 20 may be electrically connected to the interconnection layer INT3 through the contact window CW12, and the source electrode S2 may serve as a ground terminal. The drain electrode D1 and the drain electrode D2 of the inverter 20 may be electrically connected to the interconnection layer INT4 through the contact window CW21 and the contact window CW22 respectively, and the drain electrode D1 and the drain electrode D2 may serve as output terminals.

Based on the above, in this embodiment, the transistor 20A and the transistor 20B may be stacked with each other in the top-down direction Z of the substrate 22, and the transistor 20A and the transistor 20B may share the gate structure 26. Therefore, the inverter 20 of this embodiment may have a three-dimensional structure, and the area thereof can be reduced to have a relatively small dimension. More specifically, the three-dimensional inverter 20 of this embodiment can reduce the area by approximately a quarter compared to a planar inverter, so that the inverter 20 of this embodiment can be easily integrated into various electronic devices.

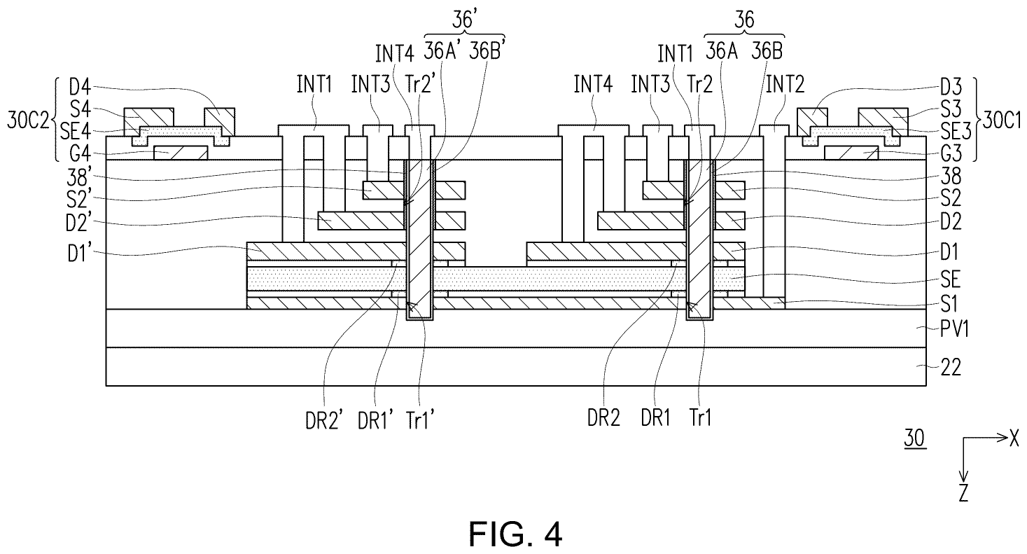

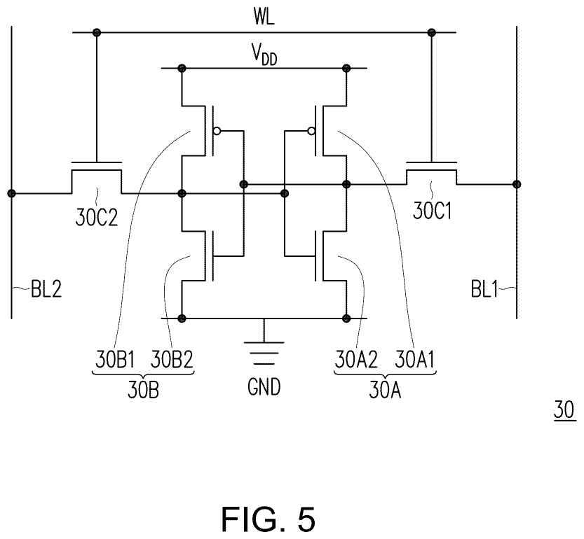

FIG. 4 is a partial cross-sectional schematic diagram of a memory unit according to an embodiment of the disclosure, and FIG. 5 is a circuit diagram of the memory unit according to an embodiment of the disclosure.

Please refer to FIG. 4 together with FIG. 5. A memory unit 30 of this embodiment may be a static random access memory (SRAM), but the disclosure is not limited thereto. In some embodiments, the memory unit 30 may include two inverters 30A and 30B cross-coupled to each other. In this embodiment, the inverter 30A and the inverter 30B have a similar structure to the inverter 20 of the above-mentioned embodiment. Briefly, the inverter 30A may include a transistor 30A1 and a transistor 30A2 stacked with each other, and inverter 30B may include a transistor 30B1 and a transistor 30B2 stacked with each other, in which the transistor 30A1 and the transistor 30B1 may have a similar structure to the transistor 20A of the above-mentioned embodiment, and the transistor 30A2 and the transistor 30B2 may have a similar structure to the transistor 20B of the above-mentioned embodiment.

More specifically, the transistor 30A1 may include a gate structure 36 (including a gate electrode 36A and a gate dielectric layer 36B), the source electrode S1, the drain electrode D1, and the semiconductor layer SE located in the trench Tr1, in which the doped region DR1 and the doped region DR2 surround the gate structure 36, so that the doped region DR1, the doped region DR2, and the semiconductor layer SE positioned there between may form a channel layer of the transistor 30A1.

More specifically, the transistor 30A2 may include the gate structure 36, the source electrode S2, the drain electrode D2, and the semiconductor layer 38 located in the trench Tr2. This means that, in this embodiment, the transistor 30A1 and the transistor 30A2 may share the gate structure 36.

More specifically, the transistor 30B1 may include a gate structure 36′ (including a gate electrode 36A′ and a gate dielectric layer 36B′), the source electrode S1, a drain electrode D1′, and the semiconductor layer SE located in a trench Tr1′, in which a doped region DR1′ and a doped region DR2′ surround the gate structure 36′, so that the doped region DR1′, the doped region DR2′, and the semiconductor layer SE positioned therebetween may form a channel layer of the transistor 30B1.

More specifically, the transistor 30B2 may include the gate structure 36′, a source electrode S2′, a drain electrode D2′, and a semiconductor layer 38′ located in a trench Tr2′. This means that, in this embodiment, the transistor 30B1 and the transistor 30B2 may share the gate structure 36′.

In this embodiment, the inverter 30A and the inverter 30B share the source electrode S1 and the semiconductor layer SE. More specifically, the transistor 30A1 and the transistor 30B1 share the source electrode S1 and the semiconductor layer SE, which can further reduce the area and have a relatively small dimension.

In some embodiments, the transistor 30A1 and the transistor 30B1 may be pull-up transistors in the memory unit 30, and the transistor 30A2 and the transistor 30B2 may be pull-down transistors in the memory unit 30, but the disclosure is not limited thereto. In this embodiment, the inverter 30A and the inverter 30B may be coupled between the power line V_{DD} and the ground line GND, in which the source electrode S1 shared by the inverter 30A and the inverter 30B may be coupled to the power line V_{DD}, and the source electrode S2 of the inverter 30A and the source electrode S2′ of the inverter 30B may each be coupled to the ground line GND.

In this embodiment, the memory unit 30 may further include a transistor 30C1 and a transistor 30C2. In some embodiments, the transistor 30C1 may be electrically connected to the inverter 30A, and the transistor 30C2 may be electrically connected to the inverter 30B. In this embodiment, the transistor 30C1 and the transistor 30C2 may be transmission gates, which may be used to control access to the memory unit 30 during write operations and/or read operations, but the disclosure is not limited thereto.

More specifically, the transistor 30C1 may include a gate structure G3, a source electrode S3, a drain electrode D3, and a semiconductor layer SE3, while the transistor 30C2 may include a gate structure G4, a source electrode S4, a drain electrode D4, and a semiconductor layer SE4. In some embodiments, the gate structure G3 and the gate structure G4 may be coupled with a word line WL, the source electrode S3 and the source electrode S4 may be coupled with a bit line BL1 and a bit line BL2 respectively, the drain electrode D3 may be coupled with the drain electrode D1 of the transistor 30A1 and the drain electrode D2 of the transistor 30A2, and the drain electrode D4 may be coupled with the drain electrode D1′ of the transistor 30B1 and the drain electrode D2′ of the transistor 30B2.

In summary, in the transistor and the manufacturing method thereof provided by the disclosure, by forming the doped region in the buffer layer to dispose the channel region contact between the source electrode and the drain electrode, the channel layer having the vertical structure is formed, and thereby the vertical transistor having a novel structure is formed.

In the inverter and the manufacturing method thereof provided by the disclosure, by stacking two transistors on the substrate, the inverter of the disclosure can have the three-dimensional structure. Furthermore, by allowing the two transistors to share the gate structure, the area of the inverter disclosed in the disclosure can be reduced to have a relatively small dimension, thereby facilitating integration into various electronic devices and improving the area utilization efficiency of electronic devices.

In the memory unit provided by the disclosure, by allowing the pull-up transistors in the two inverters cross-coupled to each other share the source electrode and the semiconductor layer, the memory unit of the disclosure can further reduce the area and have a relatively small dimension, so as to improve the area utilization efficiency of electronic devices.

What is claimed is:

1. A transistor, comprising:
a substrate;
a stacked structure disposed on the substrate, comprising:
a drain electrode;
a source electrode disposed on the drain electrode;
a semiconductor layer disposed between the drain electrode and the source electrode;
a first buffer layer disposed between the drain electrode and the semiconductor layer; and
a second buffer layer disposed between the source electrode and the semiconductor layer; and
a gate structure disposed on the substrate, wherein the gate structure extends in a top-down direction of the substrate and penetrates the stacked structure, and the gate structure comprises:
a gate electrode; and
a gate dielectric layer disposed between the gate electrode and the stacked structure.

2. The transistor as claimed in claim 1, wherein a material of the first buffer layer and the second buffer layer comprises an oxide semiconductor, and a material of the semiconductor layer comprises a polysilicon.

3. The transistor as claimed in claim 1, wherein the first buffer layer comprises a first doped region, the second buffer layer comprises a second doped region, and the first doped region and the second doped region are respectively in contact with the semiconductor layer and the gate dielectric layer.

4. The transistor as claimed in claim 1, wherein the gate structure has a columnar structure in the top-down direction of the substrate.

5. An inverter, comprising:
a substrate;
a stacked structure disposed on the substrate and comprising a first stacked structure and a second stacked structure disposed on the first stacked structure, wherein the first stacked structure comprises:
a first source electrode;
a first drain electrode disposed on the first source electrode;
a first semiconductor layer disposed between the first source electrode and the first drain electrode;
a first buffer layer disposed between the first source electrode and the first semiconductor layer; and
a second buffer layer disposed between the first drain electrode and the first semiconductor layer,
wherein the second stacked structure comprises:
a second drain electrode;
a second source electrode disposed on the second drain electrode; and
an insulating layer disposed between the second drain electrode and the second source electrode;
a gate structure disposed on the substrate, wherein the gate structure extends in a top-down direction of the substrate and penetrates the stacked structure, and the gate structure comprises:
a gate electrode; and
a gate dielectric layer disposed between the gate electrode and the stacked structure; and
a second semiconductor layer disposed between the gate structure and the second stacked structure, wherein the second semiconductor layer is in contact with the second source electrode and the second drain electrode.

6. The inverter as claimed in claim 5, wherein a width of the gate structure surrounded by the first semiconductor layer is smaller than a width of the gate structure surrounded by the second semiconductor layer.

7. The inverter as claimed in claim 5, wherein a width of the gate structure surrounded by the first semiconductor layer and a width of the gate structure surrounded by the second semiconductor layer are less than or equal to 5 microns.

8. The inverter as claimed in claim 5, wherein a material of the first buffer layer and the second buffer layer comprises an oxide semiconductor, and a material of the first semiconductor layer comprises a polysilicon.

9. The inverter as claimed in claim 5, wherein the first buffer layer comprises a first doped region, the second buffer layer comprises a second doped region, and the first doped region and the second doped region are respectively in contact with the semiconductor layer and the gate dielectric layer.

10. The inverter as claimed in claim 5, wherein a material of the second semiconductor layer comprises an oxide semiconductor.

11. The inverter as claimed in claim 5, wherein the gate structure has a columnar structure in the top-down direction of the substrate.

12. The inverter as claimed in claim 5, further comprising an interconnection layer, wherein the interconnection layer comprises:
a first interconnection layer, wherein the gate electrode is electrically connected to the first interconnection layer and serves as an input terminal;
a second interconnection layer, wherein the first source electrode is electrically connected to the second interconnection layer and serves as a power terminal;
a third interconnection layer, wherein the second source electrode is electrically connected to the third interconnection layer and serves as a ground terminal; and
a fourth interconnection layer, wherein the first drain electrode and the second drain electrode are electrically connected to the fourth interconnection layer and serve as output terminals.

13. A manufacturing method of an inverter, comprising:
forming a first stacked structure material layer comprising a first semiconductor layer;
forming a second stacked structure material layer on the first stacked structure material layer;
forming a first contact window and a second contact window, wherein the first contact window is electrically connected to a first source electrode in the first stacked structure material layer and a second source electrode in the second stacked structure material layer, and the second contact window is electrically connected to a first drain electrode in the first stacked structure material layer and a second drain electrode in the second stacked structure material layer;
removing a portion of the second stacked structure material layer to form a first trench, and forming a second semiconductor layer in the first trench, wherein the second semiconductor layer is in contact with the second source electrode and the second drain electrode;
removing a portion of the first stacked structure material layer through the first trench to form a second trench, wherein a width of the second trench is smaller than a width of the first trench; and
forming a gate structure filling the first trench and the second trench.

14. The manufacturing method of the inverter as claimed in claim 13, wherein the first semiconductor layer is formed through a low temperature polysilicon process.

15. The manufacturing method of the inverter as claimed in claim 13, wherein the second semiconductor layer is formed through an atomic layer deposition process, and a material of the second semiconductor layer comprises an oxide semiconductor.

16. The manufacturing method of the inverter as claimed in claim 13, wherein the first stacked structure material layer comprises a first buffer layer and a second buffer layer, the first buffer layer comprises a first doped region, the second buffer layer comprises a second doped region, and the first doped region and the second doped region are respectively in contact with the first semiconductor layer and the gate structure.

17. The manufacturing method of the inverter as claimed in claim 16, wherein an ion implantation process is used to form the first doped region and the second doped region.

18. A memory unit, comprising:
a first inverter and a second inverter cross-coupled to each other, wherein the first inverter and the second inverter are inverters as claimed in claim 5, wherein
the first inverter and the second inverter share the first source electrode and the first semiconductor layer.

19. The memory unit as claimed in claim 18, further comprising a first transmission gate and a second transmission gate, wherein the first transmission gate is coupled to the first inverter, and the second transmission gate is coupled to the second inverter.

20. The memory unit as claimed in claim 18 is a static random access memory.
